(19) United States
(12) Patent Application Publication
(10) Pub. No.: US 2025/0311518 A1
(43) Pub. Date: Oct. 2, 2025

(54) PLACEMENT MEMBER AND LIGHT-EMITTING DEVICE

(71) Applicant: NICHIA CORPORATION, Tokushima (JP)

(72) Inventors: Shusuke FURUSAWA, Anan-shi (JP); Eiichiro OKAHISA, Tokushima-shi (JP); Kiyoshi ENOMOTO, Tokushima-shi (JP)

(21) Appl. No.: 19/086,790

(22) Filed: Mar. 21, 2025

(30) Foreign Application Priority Data
Mar. 29, 2024 (JP) 2024-055787

(51) Int. Cl. H10H 29/85; H10H 29/01; H10H 29/24

(52) U.S. Cl. CPC H10H 29/857; H10H 29/0364; H10H 29/24

(57) ABSTRACT

A placement member includes a first surface; a plurality of electrode members arranged on the first surface, and including a first electrode member and a second electrode member that are spaced apart from each other; and a plurality of identification marks configured to identify a reference line for alignment, and including a first identification mark provided on a first electrode member side of the placement member and a second identification mark provided on a second electrode member side of the placement member, the first identification mark and the second identification mark being configured to aid in distinguishing between the first electrode and the second electrode, wherein a shape of the first identification mark and a shape of the second identification mark are different from each other.

### CROSS-REFERENCE TO RELATED APPLICATIONS

This application is based on and claims priority to Japanese Patent Application No. 2024-055787, filed on Mar. 29, 2024, the entire contents of which are incorporated herein by reference.

### BACKGROUND

### 1. Technical Field

The present disclosure relates to a placement member and a light-emitting device.

### 2. Description of Related Art

Japanese Patent Publication No. 2009-76524 describes a light-emitting device including a light-emitting element, a submount having a protruding-shaped alignment mark formed as a reference point, and a wire. In the light-emitting device, a metal member provided on the submount and an electrode of the light-emitting element mounted on the submount are connected to each other by the wire. The submount serves as a placement member on which the light-emitting element is placed.

### SUMMARY

It is an object of one embodiment of the present disclosure to provide a placement member that can improve the convenience in mounting the placement member and a light-emitting element.

It is another object of one embodiment of the present disclosure to provide a light-emitting device that can efficiently extract light.

A placement member according to an embodiment includes a first surface; a plurality of electrode members arranged on the first surface, and including a first electrode member and a second electrode member that are spaced apart from each other; and a plurality of identification marks configured to identify a reference line for alignment, and including a first identification mark provided on a first electrode member side of the placement member and a second identification mark provided on a second electrode member side of the placement member, the first identification mark and the second identification mark being configured to aid in distinguishing between the first electrode and the second electrode, wherein a shape of the first identification mark and a shape of the second identification mark are different from each other.

A light-emitting device according to an embodiment includes the above placement member; one or more light-emitting elements disposed on the first surface and configured to be electrically connected to the first electrode member and the second electrode member; and a package in which one or more placement members and the one or more light-emitting elements are arranged.

### BRIEF DESCRIPTION OF THE DRAWINGS

FIG. 1 is a perspective view of a light-emitting device according to an embodiment;

FIG. 2 is a cross-sectional view of the light-emitting device according to the embodiment, taken along line II-II of FIG. 1;

FIG. 3 is a top view of the light-emitting device according to the embodiment, from which a cover is removed;

FIG. 4 is a top view illustrating a state in which a submount is disposed on a base according to the embodiment;

FIG. 5 is a cross-sectional view of a package according to the embodiment;

FIG. 6 is a top view of the base according to the embodiment;

FIG. 7 is a bottom view of the base according to the embodiment;

FIG. 8 is a cross-sectional view of the base according to the embodiment, taken along line VIII-VIII of FIG. 6;

FIG. 9 is a top view of the submount (placement member) according to the embodiment;

FIG. 10 is a top view illustrating a state in which light-emitting element are disposed on the submount according to the embodiment; and

FIG. 11 is a side view of the submount according to the embodiment.

### DETAILED DESCRIPTION

In the present specification and the claims, polygonal shapes, such as triangular shapes and quadrangular shapes, including polygonal shapes with rounded corners, beveled corners, angled corners, reverse-rounded corners are also referred to as polygonal shapes. Further, not only shapes with such modification at corners (end of sides) but also shapes with modifications at intermediate portions of sides of the shapes are also referred to as polygonal shapes. That is, shapes that are based on polygonal shapes and partially modified are also interpreted as “polygonal shapes” in the present specification and the claims.

The same applies not only to polygonal shapes but also to terms representing specific shapes such as trapezoidal shapes, circular shapes, projections, and recesses. The same also applies when referring to sides forming such a shape. That is, even when a corner or an intermediate portion of a certain side is modified, the “side” is construed as including the modified portion. When a “polygonal shape or a “side” without partial modification is to be distinguished from a modified shape, “strict” will be added to the description as in, for example, a “strict quadrangular shape.” In the present specification and the claims, expressions such as upper/lower (above/below), right/left, front/back, front/rear (forward/backward), and toward/away merely indicate relative relationships such as relative positions, orientations, and directions and do not have to coincide with relationships during use.

Further, in the drawings, directions such as an X direction, a Y direction, and a Z direction may be indicated by using arrows. The directions of the arrows are consistent across multiple drawings of the same embodiment. In addition, in the drawings, the directions indicated by the arrows marked with an X, Y, and Z are positive directions, and directions opposite to the positive directions are negative directions. For example, the direction marked with “X” at the tip of the arrow is the X direction and is also the positive direction. A direction that is the X direction and is also the positive direction is referred to as a “positive X direction” and a direction opposite to the positive X direction is referred to as a “negative X direction.” The term “X direction” as used alone encompasses both the positive X direction and the negative X direction. The same applies to the Y direction and the Z direction.

In the present specification, when a certain object is described as being “one or more” objects, a configuration in which the number of the one or more objects is one and a configuration in which the number of the one or more objects is plural are collectively described. Therefore, when an object is described as being “one or more” objects, an embodiment including one object or a plurality of objects, an embodiment including at least one object, and an embodiment including a plurality of objects are supported.

Further, in the present specification, when an object is described as being “one or each” object, a case in which one object is described in an embodiment including the one object, one object is described in an embodiment including a plurality of objects, and a case in which each of a plurality of objects is described in an embodiment including the plurality of objects are collectively described. Therefore, the description of “one or each” object supports a case in which one object includes a described feature in an embodiment including the one object, a case in which at least one of a plurality of objects includes a described feature in an embodiment including the plurality of objects, a case in which each of a plurality of objects includes a described feature in an embodiment including the plurality of objects, and a case in which all of one or more objects include a described feature in an embodiment including the one or more objects.

Further, in the present specification, terms “member,” “portion,” and the like may be used when, for example, components and the like are described. The term “member” refers to an object that is physically treated as a single body. The object that is physically treated as a single body can also be referred to as an object that is treated as a single component in a manufacturing process. The term “portion” refers to an object that is not necessarily physically treated as a single body. For example, the term “portion” is used when a portion of a single member is treated or when a plurality of members is collectively treated as a single object.

The distinction between “member” and “portion” described above is not intended to limit the claimed scope under the doctrine of equivalents. That is, even if there is a component described as the term “member” in the claims, the applicant does not necessarily imply that physically treating the component as a single body is essential in the application of the present invention.

Further, in the present specification and the claims, if there are multiple components and these components are to be distinguished from one another, the components may be distinguished by adding terms “first,” “second,” and the like before the names of the components. Further, objects to be distinguished may be different between the specification and the claims. Therefore, even if a component recited in the claims is denoted by the same reference numeral as that of a component described in the present specification, an object specified by the component recited in the claims is not necessarily identical with an object specified by the component described in the specification.

For example, if components are distinguished by the numbers “first,” “second,” and “third” in the specification, and components with “first” and “third” in the specification are described in the claims, these components may be distinguished by the numbers “first” and “second” in the claims for ease of understanding. In this case, the components with “first” and “second” in the claims respectively refer to the components with “first” and “third” in the specification. This rule is applied not only to components but also other objects in a reasonable and flexible manner.

Embodiments of the present invention will be described below. Furthermore, specific embodiments of the present invention will be described below with reference to the drawings. The embodiments of the present invention are not limited to the specific embodiments to be described below. That is, the embodiments of the present invention are not only the embodiments that are illustrated in the drawings. The sizes, positional relationships, and the like of members illustrated in the drawings may be exaggerated in order to facilitate understanding.

### Embodiments

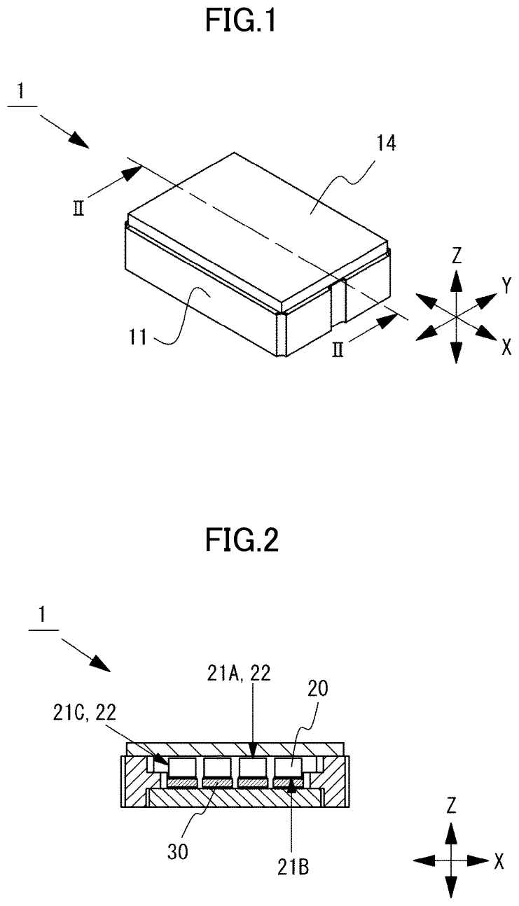

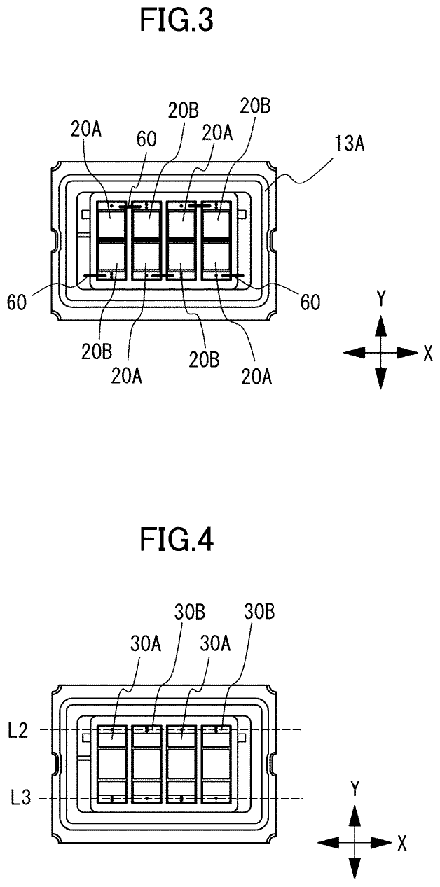

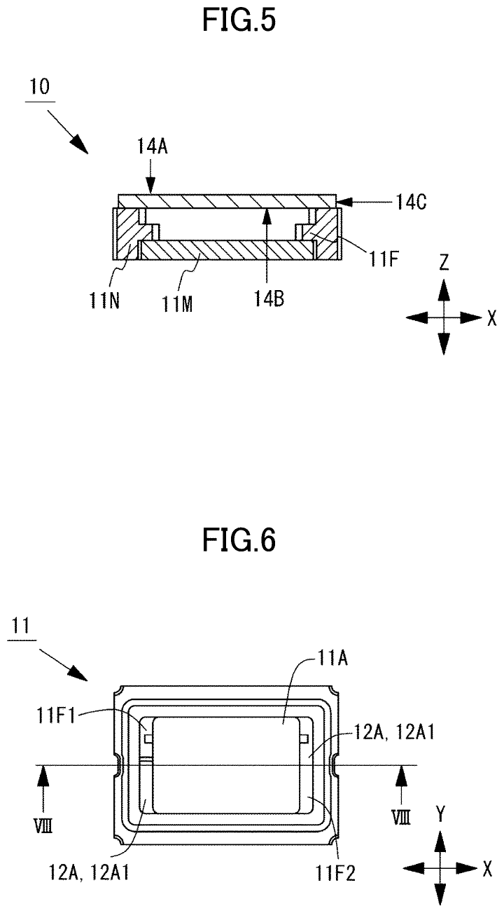

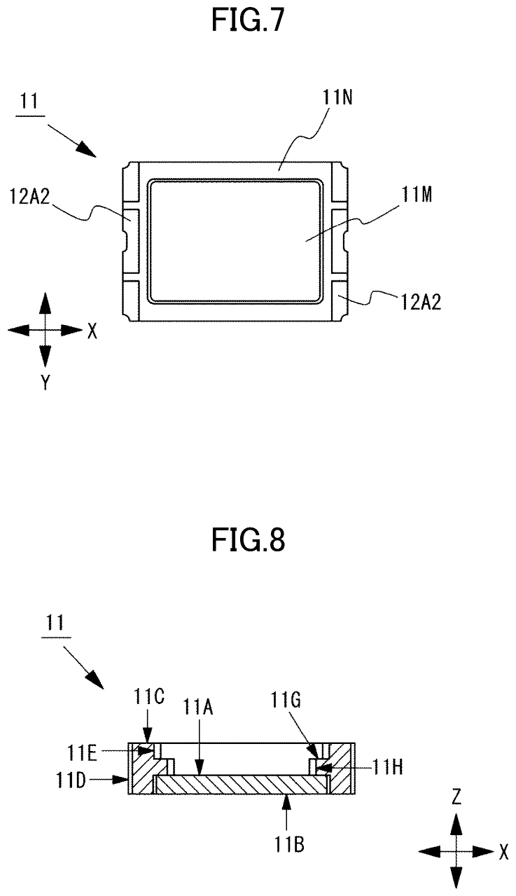

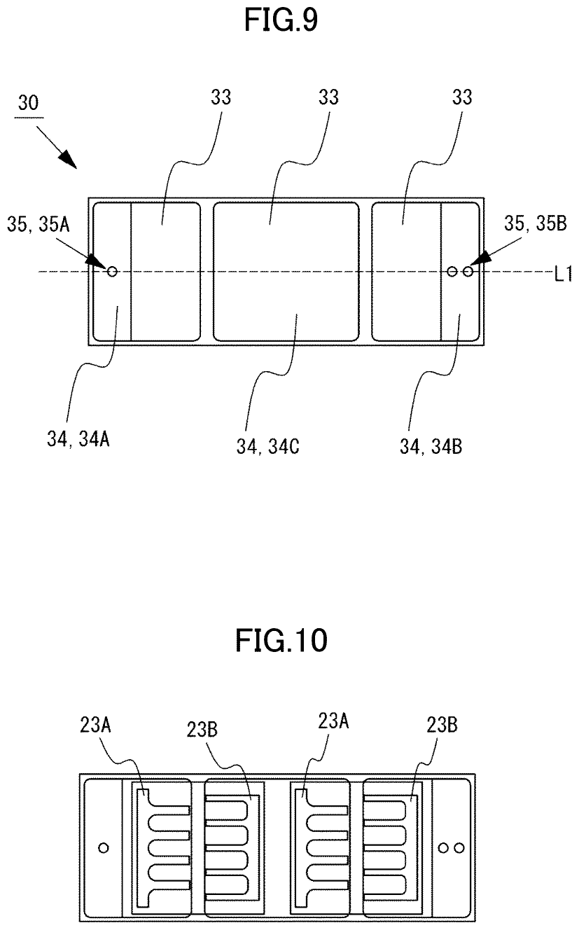

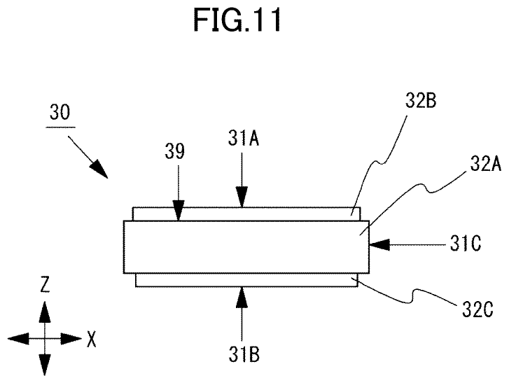

A light-emitting device 1 according to an embodiment will be described. FIG. 1 to FIG. 11 are drawings illustrating an example configuration of the light-emitting device 1. FIG. 1 is a perspective view of the light-emitting device 1. FIG. 2 is a cross-sectional view of the light-emitting device 1 taken along line II-II of FIG. 1. FIG. 3 is a top view of the light-emitting device 1 from which a cover 14 is removed. FIG. 4 is a top view illustrating a state in which a submount 30 is disposed on a base 11. Further, in FIG. 4, imaginary straight lines L2 and L3 are indicated by dashed lines. FIG. 5 is a cross-sectional view of a package 10. A cross section illustrated in FIG. 5 is taken along the line II-II of FIG. 1. FIG. 6 is a top view of the base 11. FIG. 7 is a bottom view of the base 11. FIG. 8 is a cross-sectional view of the base 11 taken along line VIII-VIII of FIG. 6. FIG. 9 is a top view of the submount 30. FIG. 10 is a top view illustrating a state in which light-emitting elements 20 are arranged on the submount 30. FIG. 11 is a side view of the submount 30.

The light-emitting device 1 includes a plurality of components. The plurality of components include the package 10, one or more light-emitting elements 20, one or more submounts 30, and a plurality of wirings 60.

The light-emitting device 1 may include a component other than the components described above. For example, the light-emitting device 1 may further include a light-emitting element in addition to the one or more light-emitting elements 20. Further, the light-emitting device 1 does not necessarily include some of the components described above.

First, each of the components will be described.

### (Package 10)

The package 10 includes the base 11 and the cover 14. The cover 14 is bonded to the base 11 to form the package 10. An internal space in the package 10 is defined as a space in which other components are arranged in the package 10. The internal space is a closed space surrounded by the base 11 and the cover 14. The internal space can be a space sealed in a vacuum state or in an airtight state.

The shape of the outer edge of the package 10 is a rectangular shape in a top view. The rectangular shape can be a rectangular shape having long sides and short sides. In the illustrated package 10, the long-side direction of the rectangular shape is the same direction as the X direction, and the short-side direction of the rectangular shape is the same direction as the Y direction. The shape of the outer edge of the package 10 is not necessarily a rectangular shape in a top view.

The internal space in which other components are arranged is formed in the package 10. A first upper surface 11A is part of a region defining the internal space of the package 10. Further, each of inner lateral surfaces 11E and a lower surface 14B is part of the region defining the internal space of the package 10.

The base 11 has the first upper surface 11A and a lower surface 11B. The base 11 has a second upper surface 11C. The base 11 has one or more outer lateral surfaces 11D. The base 11 has one or more inner lateral surfaces 11E. The one or more outer lateral surfaces 11D meet the second upper surface 11C. The one or more outer lateral surfaces 11D meet the lower surface 11B. The one or more inner lateral surfaces 11E meet the second upper surface 11C.

The shape of the outer edge of the base 11 is a rectangular shape in a top view. The shape of the outer edge of the base 11 is the shape of the outer edge of the package 10 in a top view. The shape of the outer edge of the first upper surface 11A is a rectangular shape in a top view. The rectangular shape can be a rectangular shape having long sides and short sides. The long-side direction of the first upper surface 11A is parallel to the long-side direction of the outer edge of the base 11. The shape of the outer edge of the first upper surface 11A is not necessarily a rectangular shape in a top view.

The first upper surface 11A is surrounded by the second upper surface 11C in a top view. The second upper surface 11C is a ring-like surface surrounding the first upper surface 11A in a top view. The second upper surface 11C is a rectangular ring-like surface. A frame defined by the inner peripheral edges of the second upper surface 11C is referred to as an inner frame of the second upper surface 11C, and a frame defined by the outer peripheral edges of the second upper surface 11C is referred to as an outer frame of the second upper surface 11C.

The base 11 has a recess surrounded by the inner frame of the second upper surface 11C. The recess is a portion of the base 11 that is recessed downward relative to the second upper surface 11C. The first upper surface 11A defines a portion of the recess. Each of the one or more inner lateral surfaces 11E defines a portion of the recess. The second upper surface 11C is located at a position higher than the first upper surface 11A.

The base 11 includes one or more stepped portions 11F. The stepped portions 11F have upper surfaces 11G and lateral surfaces 11H that meet the upper surfaces 11G and extend downward from the upper surfaces 11G. One stepped portion 11F has one upper surface 11G and one lateral surface 11H. The upper surfaces 11G meet the inner lateral surfaces 11E. The lateral surfaces 11H meet the first upper surface 11A.

The one or more stepped portions 11F are provided inward of the inner frame of the second upper surface 11C in a top view. The one or more stepped portions 11F are formed along a part or the entirety of the inner lateral surfaces 11E in a top view. In the base 11, the lateral surfaces 11H are inner lateral surfaces, but the lateral surfaces 11H are different surfaces from the inner lateral surfaces 11E. One or each inner lateral surface 11E and one or each lateral surface 11H is perpendicular to the first upper surface 11A. As used herein, the term “perpendicular” includes a difference of +3 degrees.

The one or more stepped portions 11F can include a first stepped portion 11F1 and a second stepped portion 11F2. The first stepped portion 11F1 and the second stepped portion 11F2 are provided such that their lateral surfaces 11H face each other. The first stepped portion 11F1 and the second stepped portion 11F2 are provided on a side of the short sides of the inner frame of the second upper surface 11C.

The base 11 includes a base portion 11M and a frame portion 11N. The base portion 11M and the frame portion 11N may be members formed of different materials. The base 11 can include a base member corresponding to the base portion 11M and a frame member corresponding to the frame portion 11N.

The base portion 11M has the first upper surface 11A. The frame portion 11N has the second upper surface 11C. The frame portion 11N has the one or more outer lateral surfaces 11D and the one or more inner lateral surfaces 11E. The frame portion 11N includes the one or more stepped portions 11F.

The lower surface of the base portion 11M constitutes a part or the entirety of the lower surface 11B of the base 11. When the lower surface of the base portion 11M constitutes a part of the lower surface 11B of the base 11, the lower surface of the frame portion 11N constitutes the remaining part of the lower surface 11B of the base 11.

The base 11 includes a plurality of wiring parts 12A. The plurality of wiring parts 12A include one or more first wiring parts 12A1 provided in the internal space of the package 10 and one or more second wiring parts 12A2 provided on the outer surface of the package 10.

One or each first wiring part 12A1 is provided on an upper surface 11G of a stepped portion 11F. The base 11 includes one or more first wiring parts 12A1 on the upper surface 11G of the first stepped portion 11F1. The base 11 includes one or more first wiring parts 12A1 on the upper surface 11G of the second stepped portion 11F2.

One or each second wiring part 12A2 is provided on the lower surface 11B of the package 10.

One or each second wiring part 12A2 is provided on the lower surface of the frame portion 11N. One or each second wiring part 12A2 may be provided on an outer surface that is different from the lower surface 11B of the package 10.

The base 11 includes one or more second wiring parts 12A2 on the lower surface 11B of the base 11, within one of two regions including the upper surface 11G of the first stepped portion 11F1 when the base 11 is divided into the two regions by an imaginary line passing along the lateral surface 11H of the first stepped portion 11F1 and parallel to the lateral surface 11H of the first stepped portion 11F1 in a top view.

The base 11 includes one or more second wiring parts 12A2 on the lower surface 11B of the base 11, within one of two regions including the upper surface 11G of the second stepped portion 11F2 when the base 11 is divided into the two regions by an imaginary line passing along the lateral surface 11H of the second stepped portion 11F2 and parallel to the lateral surface 11H of the second stepped portion 11F2 in a top view.

In the base 11, one or each first wiring part 12A1 is electrically connected to a second wiring part 12A2. One or more first wiring parts 12A1 are electrically connected to respective second wiring parts 12A2.

The base 11 has a bonding pattern 13A. The bonding pattern 13A is provided on the second upper surface 11C. The bonding pattern 13A is provided in a ring-like shape. The bonding pattern 13A is provided in a rectangular ring-like shape.

The first upper surface 11A is surrounded by the bonding pattern 13A in a top view.

The base 11 can be formed by using a ceramic as a main material. Examples of the ceramic as the main material of the base 11 include aluminum nitride, silicon nitride, aluminum oxide, or silicon carbide can be used.

As used herein, the “main material” refers to a material that occupies the greatest ratio of a target formed product in terms of weight or volume.

When a target formed product is formed of one material, that material is the main material. That is, when a certain material is the main material, the percentage of that material can be 100%. The base 11 may include a base member and

a frame member formed by using main materials different from each other. The base member can be formed by using, as a main material, a material having good heat dissipation, such as a metal, a composite containing a metal, graphite, or diamond. Examples of the metal as the main material of the base member include copper, aluminum, and iron. Examples of the composite containing a metal as the main material of the base member include copper molybdenum and copper tungsten. The frame member can be formed by using, as a main material, the ceramic exemplified as the main material of the base 11, for example.

The wiring parts 12A can be formed by using, for example, a metal material as a main material. Examples of the metal material as the main material of the wiring parts 12A include elemental metals such as Cu, Ag, Ni, Au, Ti, Pt, Pd, Cr, and W, and alloys containing these metals. Each of the wiring parts 12A can be formed of, for example, one or more metal layers.

The bonding pattern 13A can be formed by using, for example, a metal material as a main material. Examples of the metal material as the main material of the bonding pattern 13A include elemental metals such as Cu, Ag, Ni, Au, Sn, Ti, and Pd, and alloys containing these metals. The bonding pattern 13A can be formed of, for example, one or more metal layers.

The cover 14 has an upper surface 14A and the lower surface 14B. The cover 14 has one or more lateral surfaces 14C. The cover 14 is formed in a flat rectangular parallelepiped shape. The cover 14 does not necessarily have a rectangular parallelepiped shape.

The cover 14 is bonded to the base 11. The lower surface 14B of the cover 14 is bonded to the second upper surface 11C of the base 11. The cover 14 is bonded to the bonding pattern 13A of the base 11. The cover 14 is bonded to the base 11 via an adhesive.

The cover 14 has light transmissivity for transmitting light. As used herein, light transmissivity refers to having a transmittance of 80% or more with respect to light incident on the cover 14. The cover 14 may partially include a non-light-transmissive region (a region that does not have light transmissivity).

The cover 14 can be formed by using, for example, glass as a main material. The cover 14 can be formed by using, for example, sapphire as a main material.

### (Light-Emitting Element 20)

A light-emitting element 20 has an upper surface 21A, a lower surface 21B, and a plurality of lateral surfaces 21C. The shape of the upper surface 21A is a rectangular shape. The outer shape of the light-emitting element 20 in a top view is a rectangular shape. The rectangular shape is a rectangular shape having long sides and short sides. However, the shape of the upper surface 21A and the outer shape of the light-emitting element 20 in a top view are not limited thereto.

The light-emitting element 20 has a light-emitting surface 22 through which light exits. The light-emitting element 20 has one or more light-emitting surfaces 22. The upper surface 21A can be a light-emitting surface 22. In addition, the plurality of lateral surfaces 21C can be light-emitting surfaces 22. If a plurality of surfaces are light-emitting surfaces 22, the upper surface 21A can be the main light-emitting surface 22.

The light-emitting element 20 emits ultraviolet light having a peak emission wavelength in a range from 200 nm to 410 nm. However, the light emitted from the light-emitting element 20 is not limited to the above-described wavelength range.

For example, a light-emitting diode can be adopted as the light-emitting element 20. Further, for example, a vertical cavity surface emitting laser (VCSEL) can be adopted as the light-emitting element 20.

### (Submount 30)

A submount 30 is a placement member on which other components are disposed. The submount 30 has an upper surface 31A, a lower surface 31B, and one or more lateral surfaces 31C. The upper surface 31A may be referred to as a mounting surface on which the other components are mounted. The shape of the upper surface 31A is a rectangular shape. The rectangular shape of the upper surface 31A can have short sides and long sides. The shape of the upper surface 31A is not necessarily a rectangular shape.

The outer shape of the submount 30 in a top view is a rectangular shape. The rectangular shape of the submount 30 can have short sides and long sides. The outer shape of the submount 30 in a top view is not necessarily a rectangular shape. The submount 30 can have an outer shape in which the length of a side in one direction (hereinafter referred to as a “widthwise direction” of the submount 30) is smaller than the length of a side in a direction (hereinafter referred to as a “lengthwise direction” of the submount 30) perpendicular to the widthwise direction in a top view. In the illustrated submount 30, the widthwise direction is the same direction as the X direction, and the lengthwise direction is the same direction as the Y direction.

The submount 30 includes a substrate 32A and an upper metal member 32B. The submount 30 includes a plurality of upper metal members 32B. The submount 30 may further include a lower metal member 32C. The upper metal members 32B are provided on the upper surface of the substrate 32A. The upper surface of the substrate 32A can be referred to as a placement surface 39 (an example of a first surface) on which the upper metal members 32B are placed. The lower metal member 32C is provided on the lower surface of the substrate 32A.

The upper metal members 32B and the lower metal member 32C each have a higher thermal conductivity than the thermal conductivity of the substrate 32A. By providing the metal members on the upper side and the metal member on the lower side of the submount 30, the heat dissipation performance of the submount 30 can be improved.

The submount 30 further includes a wiring layer 33 formed as a plurality of parts at a plurality of locations. The wiring layer 33 as the plurality of parts is provided on the upper metal members 32B. The wiring layer 33 is electrically connected to other components disposed on the submount 30. The wiring layer 33 is connected to electrodes of other components. The upper metal members 32B are connected to the electrodes of the other components via the wiring layer 33. The wiring layers 33 and the upper metal members 32B may be collectively referred to as electrode members 34. The electrode members 34 are provided on the placement surface 39.

The submount 30 includes a plurality of electrode members 34. The plurality of electrode members 34 are separated from each other. The plurality of upper metal members 32B are separated from each other in a top view.

The plurality of electrode members 34 include a first electrode member 34A and a second electrode member 34B. Further, the plurality of electrode members 34 includes one or more third electrode members 34C. The first electrode member 34A has one wiring layer 33. The second electrode member 34B has one wiring layer 33. Each of the one or more third electrode members 34C has one wiring layer 33.

The plurality of electrode members 34 are arranged in the lengthwise direction of the submount 30. Of the plurality of electrode members 34, two electrode members 34 disposed at both ends in the lengthwise direction of the submount 30 are the first electrode member 34A and the second electrode member 34B. In other words, the first electrode member 34A is provided at one end of the two ends of the submount 30, and the second electrode member 34B are provided at the other end. The first electrode member 34A and the second electrode member 34B are arranged in the lengthwise direction of the submount 30. The one or more third electrode members 34C are provided between the first electrode member 34A and the second electrode member 34B in a top view.

The width of the first electrode member 34A is smaller than the width of a third electrode member 34C in the lengthwise direction of the submount 30. The width of the first electrode member 34A is 55% or more and 90% or less of the width of the third electrode member 34C in the lengthwise direction of the submount 30. This makes it possible to reduce the width of the submount 30 in the lengthwise direction.

The width of the second electrode member 34B is smaller than the width of the third electrode 34C in the lengthwise direction of the submount 30. The width of the second electrode member 34B is 55% or more and 90% or less as wide as the width of the third electrode member 34C in the lengthwise direction of the submount 30. This makes it possible to reduce the width of the submount 30 in the lengthwise direction.

The width of the first electrode member 34A is the same as the width of the second electrode member 34B in the lengthwise direction of the submount 30. As used herein, “same” includes a difference of 10% or less. With this configuration, the width of the submount 30 in the lengthwise direction can be reduced.

The widths of the first electrode member 34A, the second electrode member 34B, and the third electrode member 34C in the widthwise direction of the submount 30 are the same. The plurality of electrode members 34 have the same width in the widthwise direction of the submount 30. As used herein, “same” includes a difference of 10% or less. With this configuration, the width of the submount 30 in the widthwise direction can be reduced.

The outer shape of the first electrode member 34A in a top view is a rectangular shape. The outer shape of the second electrode member 34B in a top view is a rectangular shape. The outer shape of the third electrode member 34C in a top view is a rectangular shape. Each of the first electrode member 34A and the second electrode member 34B has a smaller width in the lengthwise direction of the submount 30 than in the widthwise direction of the submount 30. By forming each of the first electrode member 34A and the second electrode member 34B in such a shape, the length of the submount 30 in the lengthwise direction can be reduced.

The submount 30 includes one or more identification marks 35. The submount 30 includes a first identification mark 35A and a second identification mark 35B, both of which are identification marks 35. In other words, the submount 30 has a plurality of identification marks 35 including the first identification mark 35A and the second identification mark 35B.

A reference line L1 for alignment can be identified by the plurality of identification marks 35. For example, the reference line L1 for alignment can be a straight line connecting two identification marks 35. Alternatively, the reference line L1 for alignment can be a straight line connecting two points identified based on a plurality of identification marks 35. The reference line L1 can be identified based on the first identification mark 35A and the second identification mark 35B.

For example, the reference line L1 for alignment can be used to determine the mounting positions of other components to be mounted on the submount 30. Further, for example, the reference line L1 for alignment can be used to determine the mounting position of the submount 30 when the submount 30 is to be mounted on another component.

The shape of the first identification mark 35A and the shape of the second identification mark 35B are different from each other. With the shape of first identification mark 35A and the shape of the second identification mark 35B different from each other, the first identification mark 35A and the second identification mark 35B can be distinguished from each other. This allows for identification based on whether an identification mark is the first identification mark 35A or the second identification mark 35B.

For example, the orientation of the submount 30 can be identified. Further, for example, it is possible to identify which one of electrode members 34 arranged at both ends is the first electrode member 34A, and connect an appropriate electrode of another component to the first electrode member 34A. That is, a first electrode and a second electrode connected to the first electrode member 34A and the second electrode member 34B of the submount 30 can be distinguished from each other.

The shape of the first identification mark 35A is constituted by one mark. The shape of the second identification mark 35B is constituted by a plurality of marks. The number of marks constituting the shape of the second identification mark 35B is larger than the number of marks constituting the shape of the first identification mark 35A. The first identification mark 35A and the second identification mark 35B can be distinguished from each other based on a difference in the number of marks.

In the illustrated example of the submount 30, the first identification mark 35A has a shape constituted by one circular mark in a top view, and the second identification mark 35B has a shape constituted by two circular marks aligned with each other in a top view. The two circular marks constituting the shape of the second identification mark 35B are aligned with each other in the lengthwise direction of the submount 30.

In a top view, the reference line L1 passes through the one mark constituting the shape of the first identification mark 35A and the plurality of marks constituting the shape of the second identification mark 35B. These marks are provided at positions through which the reference line L1 passes. Accordingly, the reference line L1 can be accurately identified.

The width of the second identification mark 35B is greater than the width of the first identification mark 35A in the lengthwise direction of the submount 30. This could increase the width of the submount 30 in the lengthwise direction, but also allows the reference line L1 to be accurately identified.

The first identification mark 35A is provided on a first electrode member 34A side of the submount 30, and the second identification mark 35B is provided on a second electrode member 34B side of the submount 30. In the illustrated example, the first identification mark 35A is provided on the first electrode member 34A and the second identification mark 35B is provided on the second electrode member 34B. However, the identification marks 35 are not necessarily provided on the electrode members 34.

Examples of a method of providing an identification mark 35 on an electrode member 34 include a method of further disposing the identification mark 35 on the electrode member 34, a method of forming the identification mark 35 together with the electrode member 34 when the electrode member 34 is formed, and the like. Examples of the method of forming the identification mark 35 together with the electrode member 34 when the electrode member 34 is formed include a method of forming a recess having a circular shape in a top view in the electrode member 34.

The wiring layer 33 of the first electrode member 34A is located closer to the second electrode member 34B than the first identification mark 35A is to the second electrode member 34B in a top view. The wiring layer 33 of the second electrode member 34B is located closer to the first electrode member 34A than the second identification mark 35B is to the first electrode member 34A in a top view.

The first identification mark 35A and the second identification mark 35B are provided in regions close to both ends of the submount 30 in the lengthwise direction in a top view. The first identification mark 35A is provided at a position closer to the end, farther from the second electrode member 34B, of the two ends of the first electrode member 34A in the lengthwise direction of the submount 30. The second identification mark 35B is provided at a position closer to the end, farther from the first electrode member 34A, of the two ends of the second electrode member 34B in the lengthwise direction of the submount 30.

The wiring layer 33 is provided between the first identification mark 35A and the second identification mark 35B in the lengthwise direction of the submount 30. The one or more third electrode members 34C are provided between the first identification mark 35A and the second identification mark 35B in the lengthwise direction of the submount 30.

The substrate 32A has an insulating property. The substrate 32A is formed of, for example, silicon nitride, aluminum nitride, or silicon carbide. As a main material of the substrate 32A, a ceramic having a relatively good heat dissipation property (a high thermal conductivity) may be selected.

As a main material of the upper metal members 32B, a metal such as copper or aluminum is used. Each of the upper metal members 32B have one or more metal layers. Each of the upper metal members 32B may have a plurality of metal layers formed of different metals as main materials.

As a main material of the lower metal member 32C, a metal such as copper or aluminum is used. The lower metal member 32C has one or more metal layers. The lower metal member 32C may have a plurality of metal layers formed of different metals as main materials.

The wiring layer 33 can be formed by using a metal. For example, the wiring layer 33 can be formed by using AuSn solder (a metal layer of AuSn).

For example, the length of the submount 30 in the short-side direction or the widthwise direction is 500 μm or more and 1,500 μm or less. Further, the length of the submount 30 in the long-side direction or the lengthwise direction is 1,000 μm or more and 3,000 μm or less. A difference between the length of the submount 30 in the lengthwise direction and the length of the submount 30 in the widthwise direction is 500 μm or more and 2,500 μm or less.

For example, the thickness of the submount 30 (the width of the submount 30 in a direction perpendicular to the upper surface 31A) is 100 μm or more and 1,000 μm or less. Further, for example, the thickness of the substrate 32A is 100 μm or more and 1,000 μm or less. Further, for example, the thickness of each of the upper metal members 32B is 25 μm or more and 150 μm or less. Further, for example, the thickness of the lower metal member 32C is 25 μm or more and 150 μm or less. Further, for example, the thickness of the wiring layer 33 is 0.1 μm or more and 10 μm or less.

### (Wiring 60)

Wiring 60 is a linear electrically-conductive material with both ends serving as bonding portions. The bonding portions at both ends are portions to be bonded to other components. The wiring 60 is used for electrical connection between two components. The wiring 60 is, for example, a metal wire. For example, gold, aluminum, silver, copper, or the like can be used as the metal.

Next, the light-emitting device 1 will be described.

### (Light-Emitting Device 1)

In the light-emitting device 1, one or more light-emitting elements 20 are disposed in the internal space of the package 10. The one or more light-emitting elements 20 are disposed on the base 11. The one or more light-emitting elements 20 are disposed on the first upper surface 11A.

The one or more light-emitting elements 20 can include a plurality of light-emitting elements 20 arranged in a matrix. In the light-emitting device 1, the plurality of light-emitting elements 20 can be arranged in a matrix, that is, in a plurality of rows and a plurality of columns. In the illustrated light-emitting device 1, the row direction in the matrix arrangement is the same direction as the X direction, and the column direction is the same direction as the Y direction.

In the light-emitting device 1, the plurality of light-emitting elements 20 are arranged at short intervals in a matrix. An interval between adjacent light-emitting elements 20 is 50 μm or more and 500 μm or less. An interval between adjacent light-emitting elements 20 in the row direction can be larger than an interval between adjacent light-emitting elements 20 in the column direction. A difference between the interval between the adjacent light-emitting elements 20 in the row direction and the interval between the adjacent light-emitting elements 20 in the column direction can be 0 μm or more and 450 μm or less.

In the light-emitting device 1, one or more light-emitting elements 20 are disposed on the submount 30. The one or more light-emitting elements 20 are disposed on the first upper surface 11A via the submount 30. The one or more light-emitting elements 20 are disposed on one or each submount 30.

One or each light-emitting element 20 is connected to the electrode members 34 of the submount 30. The first electrode member 34A of the submount 30 is connected to a first electrode of the light-emitting element 20. The second electrode member 34B of the submount 30 is connected to a second electrode of the light-emitting element 20. In a case where a plurality of light-emitting elements 20 are disposed on the submount 30, a light-emitting element 20 different from a light-emitting element 20 connected to the first electrode member 34A is connected to the second electrode member 34B.

A first electrode of a light-emitting element 20 is connected to the wiring layer 33 of the first electrode member 34A, and the first identification mark 35A and the light-emitting element 20 do not overlap each other in a top view.

A second electrode of another light-emitting element 20 is connected to the wiring layer 33 of the second electrode member 34B, and the second identification mark 35B and the light-emitting element 20 do not overlap each other in a top view. In a state in which one or more light-emitting elements 20 are disposed on the submount 30, the first identification mark 35A and the second identification mark 35B do not overlap the one or more light-emitting elements 20 in a top view.

The one or more light-emitting elements 20 include one or more first light-emitting elements 20A each connected to the first electrode member 34A, and one or more second light-emitting elements 20B each connected to the second electrode member 34B. In the light-emitting device 1, the number of the first light-emitting elements 20A is equal to the number of submounts 30, and the number of the second light-emitting elements 20B is equal to the number of the submounts 30.

One or each of the first light-emitting elements 20A is connected to the first electrode member 34A and the third electrode member 34C. One or each of the second light-emitting elements 20B is connected to the third electrode member 34C and the second electrode member 34B. In a case where two light-emitting elements 20, which are one first light-emitting element 20A and one second light-emitting element 20B, are disposed on the submount 30, the second light-emitting element 20B is connected to the third electrode member 34C to which the first light-emitting element 20A is connected. Specifically, a second electrode of the first light-emitting element 20A and a first electrode of the second light-emitting element 20B are connected to the third electrode member 34C.

The reference line L1 can be used when the one or more light-emitting elements 20 are to be disposed on the submount 30. In a top view, a lateral surface 21C of each of the light-emitting elements 20 disposed on the submount 30 is parallel or perpendicular to the reference line L1. In addition, the center of the width of each of the light-emitting elements 20 in a direction perpendicular to the reference line L1 passes through the reference line L1 in a top view.

The first electrode of one of the light-emitting elements 20 is connected to the first electrode member 34A, and the second electrode of another one of the light-emitting elements 20 is connected to the second electrode member 34B.

Therefore, the first electrode can be identified as being located on the first identification mark 35A side, and the second electrode can be identified as being located on the second identification mark 35B side.

In this manner, the plurality of identification marks 35 provided on the submount 30 enables alignment of components when the components are mounted and allows electrodes to be distinguished from each other. Accordingly, the submount 30 capable of improving the convenience in mounting the submount 30 and the light-emitting elements 20 can be provided.

The one or more light-emitting elements 20 disposed on the submount 30 are electrically connected to the first electrode member 34A and the second electrode member 34B.

In the light-emitting device 1, one or more submounts 30 are disposed in the internal space of the package 10. The one or more submounts 30 are disposed on the base 11. The one or more submounts 30 are disposed on the first upper surface 11A.

Each of the submounts 30 is disposed on the first upper surface 11A such that a first electrode member 34A and a second electrode member 34B are arranged in a first direction. In the illustrated light-emitting device 1, the first direction is the same direction as the positive Y direction. Each of the submounts 30 is disposed such that the lengthwise direction of each of the submounts 30 is parallel to the widthwise direction of the package 10.

The one or more submounts 30 can include a plurality of submounts 30 arranged side by side in a second direction perpendicular to the first direction in a top view. In the illustrated light-emitting device 1, the second direction is the same direction as the X direction.

In the light-emitting device 1, the number of submounts 30 arranged in the first direction is smaller than the number of submounts 30 arranged in the second direction. In the illustrated example of the light-emitting device 1, the number of submounts 30 arranged in the first direction is one, and the number of submounts 30 arranged in the second direction is four.

In the light-emitting device 1, the number of light-emitting elements 20 arranged in the first direction is smaller than the number of light-emitting elements 20 arranged in the second direction. A difference between the number of light-emitting elements 20 arranged in the first direction and the number of light-emitting elements 20 arranged in the second direction is smaller than a difference between the number of submounts 30 arranged in the first direction and the number of submounts 30 arranged in the second direction.

In the light-emitting device 1, the number of submounts 30 arranged in the second direction is larger than the number of light-emitting elements 20 arranged in the first direction. With this configuration, light-emitting elements 20 can be arranged on the first upper surface 11A, which is wider in the second direction than in the first direction, by effectively utilizing the first upper surface 11A.

The one or more submounts 30 include a first submount 30A and a second submount 30B that are arranged next to each other. In the first submount 30A, a first electrode member 34A is located at a position forward in the first direction from a second electrode member 34B. In the second submount 30B, a second electrode member 34B is located at a position forward in the first direction from a first electrode member 34A. In the submounts 30 arranged next to each other, the position of a first identification mark 35A of one of the submounts 30 is different from the position of a first identification mark 35A of the other submount 30 by 180 degrees in a top view, and the position of a second identification mark 35B of the one of the submounts 30 is different from the position of a second identification mark 35B of the other submount 30 by 180 degrees in a top view. With this arrangement, wiring 60 can be easily connected as will described later.

In the light-emitting device 1, the thickness (the width in the upper-lower direction) of a light-emitting element 20 is greater than the height from the first upper surface 11A of the package 10 to the upper surface 11G of a stepped portion 11F. That is, even if the light-emitting element 20 is directly disposed on the first upper surface 11A without a submount 30, the upper surface 21A of the light-emitting element 20 is located at a position higher than the upper surface 11G. Therefore, in the light-emitting element 20 having the upper surface 21A as the main light-emitting surface, the stepped portion 11F does not hinder light exiting from the main light-emitting surface. However, in the light-emitting device 1, the light-emitting element 20 is disposed on the first upper surface 11A via the submount 30, and the upper surface 21A of the light-emitting elements 20 is brought even closer to the upper surface 14A of the package. This allows light exiting from lateral surfaces 21C of the light-emitting element 20 to efficiently exit from the upper surface 14A of the light-emitting device 1, and thus light can be efficiently extracted.

In the light-emitting device 1, the thickness (the width in the upper-lower direction) of the submount 30 is smaller than the height from the first upper surface 11A of the package 10 to the upper surface 11G of the stepped portion 11F. As the thickness of the submount 30 increases, a heat dissipation path through which heat generated in the light-emitting element 20 is transferred from the first upper surface 11A to the package 10 becomes longer. Therefore, in consideration of heat dissipation, it is preferable that the submount 30 is not too thick.

Reference lines L1 identified based on the submounts 30 can be used to mount a plurality of submounts 30 are mounted side by side. The submounts 30 are mounted in the package 10 such that the reference lines L1 are parallel to the short-side direction of the package 10. The plurality of submounts 30 are mounted on the first upper surface 11A such that the reference lines L1 identified based on the submounts 30 are parallel to each other.

In a top view, the imaginary straight line L2 connecting one mark constituting a first identification mark 35A of one of two first submounts 30A, which are arranged on both sides of a second submount 30B, to one mark constituting a first identification mark 35A of the other first submount 30A does not pass through any of two marks constituting a second identification mark 35B of the second submount 30B. However, the imaginary straight line L2 may pass through any of the two marks constituting the second identification mark 35B.

In a top view, the imaginary straight line L3 connecting one mark constituting a first identification mark 35A of one of two second submounts 30B, which are arranged on both sides of a first submount 30A, to one mark constituting a first identification mark 35A of the other second submount 30B does not pass through any of two marks constituting a second identification mark 35B of the first submount 30A.

The light-emitting device 1 includes a plurality of wirings 60 configured to electrically connect one or more light-emitting elements 20 to the package 10. The plurality of wirings 60 include wiring 60 bonded to a first wiring part 12A1 and a first electrode member 34A. The plurality of wirings 60 include wiring 60 bonded to a first wiring part 12A1 and a second electrode member 34B.

The plurality of wirings 60 include wiring 60 bonded to a first wiring part 12A1 provided on the first stepped portion 11F1 and to a submount 30. The plurality of wirings 60 include wiring 60 bonded to a first wiring part 12A1 provided on the second stepped portion 11F2 and to a submount 30.

In the illustrated example of the light-emitting device 1, the plurality of wirings 60 include wiring 60 bonded to a first wiring part 12A1 provided on the first stepped portion 11F1 and to a second electrode member 34B of a submount 30, and wiring 60 bonded to a first wiring part 12A1 provided on the second stepped portion 11F2 and to a first electrode member 34A of a submount 30.

The plurality of wirings 60 include wiring 60 bonded to a first submount 30A and a second submount 30B. Specifically, the plurality of wirings 60 include wirings 60 bonded to a first electrode member 34A and a second electrode member 34B of two different submounts 30. By bonding the wirings 60 in this manner, a plurality of light-emitting elements 20 disposed on two submounts 30 can be electrically connected in series. One or more light-emitting elements 20 included in the light-emitting device 1 are electrically connected in series.

Although a certain embodiment according to the present invention has been described above, the placement member and the light-emitting device according to the present invention is not strictly limited to the embodiment described above. In other words, the present invention can be achieved without being limited to the external shapes and the structures of the placement member and the light-emitting device in the embodiment described above. The present invention may be applied without requiring all the components being provided. For example, if some of the components of the placement member or the light-emitting device disclosed in the embodiment are not recited in the claims, it is intended that the degree of freedom in design by one skilled in the art, such as substitutions, omissions, shape modifications, and changes in materials of the some of the components, is allowed and the invention stated in the claims is still applicable.

The light-emitting device according to the embodiment can be utilized in a sterilization device. That is, the sterilization device can be considered as an example of use to which the present invention is applied. The present invention is not limited to this example, and can be utilized in various applications such as exposure devices, processing devices, paint curing, water sterilization, air sterilization, and semiconductor manufacturing.

According to one or more embodiments of the present disclosure, a placement member capable of improving the convenience in mounting the placement member and a light-emitting element can be provided.

What is claimed is:

1. A placement member comprising:
a first surface;
a plurality of electrode members arranged on the first surface, and including a first electrode member and a second electrode member that are spaced apart from each other; and
a plurality of identification marks configured to identify a reference line for alignment, and including a first identification mark provided on a first electrode member side of the placement member and a second identification mark provided on a second electrode member side of the placement member, the first identification mark and the second identification mark being configured to aid in distinguishing between the first electrode and the second electrode, wherein
a shape of the first identification mark and a shape of the second identification mark are different from each other.

2. The placement member according to claim 1, wherein the reference line is identifiable based on the first identification mark and the second identification mark.

3. The placement member according to claim 1, wherein
the first identification mark is provided on the first electrode member, and
the second identification mark is provided on the second electrode member.

4. The placement member according to claim 1, wherein
the shape of the first identification mark is constituted by one mark, and
the shape of the second identification mark is constituted by a plurality of marks.

5. The placement member according to claim 4, wherein the one mark constituting the shape of the first identification mark and the plurality of marks constituting the shape of the second identification mark are provided at positions through which the reference line passes in a top view.

6. The placement member according to claim 1, wherein
the first electrode member and the second electrode member are arranged in a first direction,
the first identification mark is provided at a position closer to an end, farther from the second electrode member, of two ends of the first electrode member in the first direction, and
the second identification mark is provided at a position closer to an end, farther from the first electrode member, of two ends of the second electrode member in the first direction.

7. The placement member according to claim 6, wherein
the plurality of electrode members further include one or more third electrode members provided between the first electrode member and the second electrode member, and
in a top view, a width of the placement member in the first direction is greater than a width of the placement member in a direction perpendicular to the first direction.

8. A light-emitting device comprising:
the placement member according to claim 1;
one or more light-emitting elements electrically connected to the first electrode member and the second electrode member; and
a package in which the placement member and the one or more light-emitting elements are arranged.

9. A light-emitting device comprising:
the placement member according to claim 7;
one or more light-emitting elements; and
a package in which the placement member and the one or more light-emitting elements are arranged, wherein
the one or more light-emitting elements include
a first light-emitting element connected to the first electrode member and the one or more third electrode members of the placement member, and
a second light-emitting element connected to the one or more third electrode members and the second electrode member, and
the first light-emitting element and the second light-emitting element are located at positions through which a line segment connecting the first identification mark and the second identification mark passes in a top view.
